(19) United States
(12) Patent Application Publication
(10) Pub. No.: US 2012/0199880 A1
(43) Pub. Date: Aug. 9, 2012

(54) SEMICONDUCTOR DEVICE AND PRODUCTION METHOD THEREOF

(75) Inventor: Koichi Matsuda, Kawasaki-shi (JP)

(73) Assignee: CANON KABUSHIKI KAISHA, Tokyo (JP)

(21) Appl. No.: 13/497,798

(22) PCT Filed: Nov. 17, 2010
(86) PCT No.: PCT/JP2010/070951

§ 371 Date: Mar. 22, 2012

(30) Foreign Application Priority Data
Dec. 2, 2009 (JP) 2009-274620

(51) Int. Cl. H01L 29/78; H01L 21/20

(52) U.S. Cl. 257/192; 257/288; 438/478; 257/E29.255; 257/E21.09

(57) ABSTRACT

In order to solve a problem that, in an initial stage of film growth in a plasma CVD method, it is difficult to form a silicon layer which is excellent in crystallinity, provided is a semiconductor device, including: a substrate; a crystalline silicon layer; a titanium oxide layer containing titanium oxide as a main component; and a pair of electrodes electrically connected to the crystalline silicon layer, in which: the titanium oxide layer and the crystalline silicon layer are formed on the substrate in the mentioned order from the substrate side; and the titanium oxide layer and the crystalline silicon layer are formed in contact to each other.

### TECHNICAL FIELD

The present invention relates to a semiconductor device, which includes a crystalline silicon layer as an active layer, and a production method thereof.

### BACKGROUND ART

As a semiconductor device used in an active matrix display device, a thin-film transistor which includes a crystalline silicon film as an active layer has attracted attention. A crystalline silicon film has better electrical characteristics and may be formed in larger size in comparison with an amorphous silicon film. Further, the crystalline silicon film has high resistance against current stress, and hence there is an advantage that a shift in threshold voltage (Vth), which is observed after driving the semiconductor device for a long period of time, is small.

However, compared with a crystalline silicon film formed by a rapid thermal annealing (RTA) method or a laser annealing method, a crystalline silicon film formed by a vapor-phase growth method such as a plasma chemical vapor deposition (CVD) method is lower in crystallinity at a time immediately after a silicon film is deposited. Therefore, a carrier mobility thereof is relatively small. Therefore, improving crystallinity, that is, increasing a ratio of crystal in the crystalline silicon film has been a task to be solved.

As another crystalline semiconductor device, there may be exemplified a photovoltaic device and a photo sensor. Among layer configurations of the photovoltaic device, it is known that crystallinity of an i-type layer is an important factor in improving photoelectric conversion efficiency. Also for increase of a throughput in particular, it is desired to form a silicon film which is excellent in crystallinity at a time immediately after a film is deposited by the plasma CVD method.

H. Kakinuma (J.A.P 70(12)15, December, 1991 P. 7374) reports that, in a crystalline silicon film formed by the plasma CVD method, crystallization proceeds in an upper portion of the film, but there still exists an amorphous in a lower portion thereof. This indicates that, in an initial stage of film growth in the plasma CVD method, it is difficult to form a silicon layer which is excellent in crystallinity.

### SUMMARY OF INVENTION

### Technical Problem

Crystallinity is what influences the characteristics of the crystalline silicon semiconductor device, and as the crystallinity becomes higher, electrical characteristics are improved. Generally, in a semiconductor device such as a thin-film transistor or a photovoltaic device, an improvement of crystallinity directly contributes to a characteristic improvement thereof.

Therefore, the present invention has an object to provide a crystalline silicon semiconductor device having excellent crystallinity and electrical characteristics, and a production method thereof.

### Solution to Problem

In order to solve the above-mentioned problems, the present invention provides a semiconductor device, including; a substrate, a crystalline silicon layer, a titanium oxide layer containing titanium oxide as a main component, and a pair of electrodes electrically connected to the crystalline silicon layer; in which; the titanium oxide layer and the crystalline silicon layer are formed on the substrate in the mentioned order from the substrate side, and the titanium oxide layer and the crystalline silicon layer are formed in contact to each other.

The present invention also provides a production method of a semiconductor device, including; forming a titanium oxide layer containing titanium oxide as a main component, and forming a crystalline silicon layer by a vapor-phase growth method, the crystalline silicon layer being formed in contact with the titanium oxide layer.

### Advantageous Effects of Invention

According to the present invention, it is possible to provide a crystalline silicon semiconductor device having excellent crystallinity and electrical characteristics, and a production method thereof.

### BRIEF DESCRIPTION OF DRAWINGS

FIGS. 1A, 1B, 1C and 1D are schematic cross-sectional views each illustrating a semiconductor device according to the present invention.

FIG. 2 is a schematic cross-sectional view of a photovoltaic device which is the semiconductor device according to the present invention.

FIGS. 3A and 3B are a schematic cross-sectional view and a schematic plan view, respectively, of a photo sensor which is the semiconductor device according to the present invention.

FIG. 4 is a graph showing a spectrum of a silicon layer, which is obtained by Raman spectroscopy.

### DESCRIPTION OF EMBODIMENTS

Hereinafter, preferred embodiments according to the present invention are described with reference to the attached drawings.

[Top-Gate Staggered TFT]

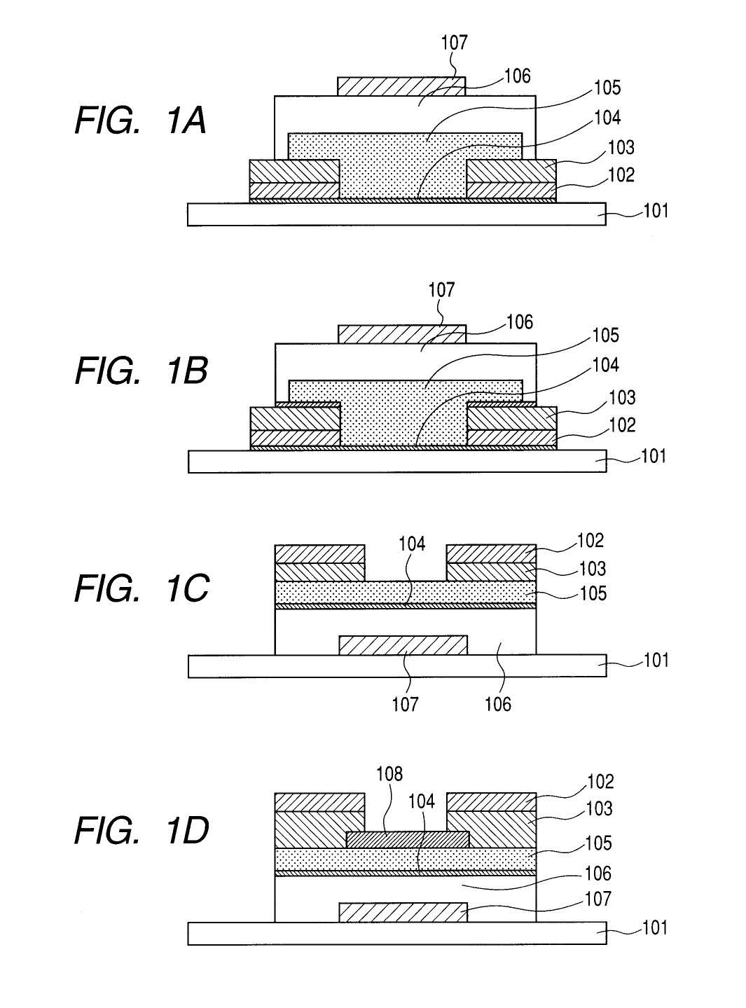

FIG. 1A illustrates a schematic cross-sectional view of a top-gate staggered thin-film transistor (TFT) as a typical example of a semiconductor device according to an embodiment of the present invention.

In FIG. 1A, the top-gate staggered TFT includes a glass substrate 101, and a source electrode layer 102 and a drain electrode layer 102, which are formed on the glass substrate 101 and made of a metal. Further, the top-gate staggered TFT includes ohmic contact layers formed of impurity-containing semiconductor layers 103. A titanium oxide layer 104 is formed under the source and drain electrode layers 102 which are made of a metal. The source and drain electrode layers 102 and the impurity-containing semiconductor layers 103 are formed in an island shape by lamination and patterning. Therefore, a part of the titanium oxide layer 104 is exposed. The titanium oxide layer 104 may contain materials other than titanium oxide, but is preferred to contain titanium oxide as a main component. A crystalline silicon layer 105 is formed on the titanium oxide layer 104. The crystalline silicon layer 105 is formed in contact with the titanium oxide layer 104 on the glass substrate side, and is formed in ohmic contact with the source and drain electrode layers 102 on the glass substrate side.

In the semiconductor device according to the present invention, the crystalline silicon layer is defined as a silicon layer in which, among conceivable configurations of the silicon layer, a Raman shift is observed by Raman spectroscopy at 520 cm⁻¹, and in particular, a volume fraction of crystal is equal to or larger than 20%. In the present invention, if the volume fraction of crystal is lower than 20%, even if a Raman shift is observed at 520 cm⁻¹, the silicon layer is defined as a non-crystalline silicon layer. If a Raman shift is not observed at 520 cm⁻¹, the silicon layer is defined as an amorphous silicon layer. Note that, also in an amorphous silicon layer, there exists an area having a similar structure as the crystalline silicon in short ranges.

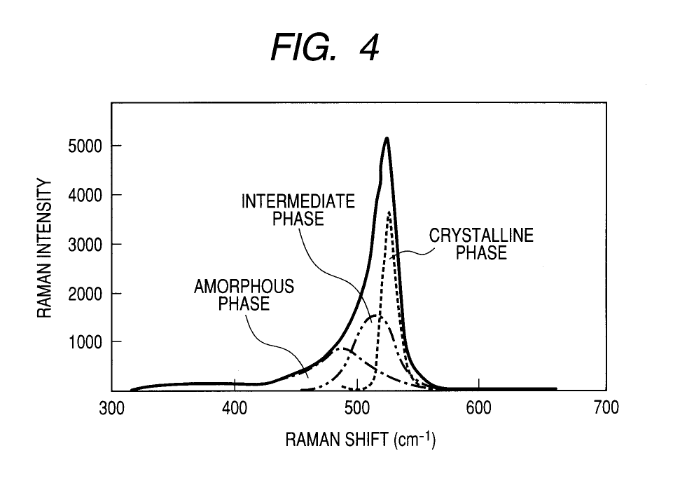

FIG. 4 shows a typical spectrum of a silicon layer according to the present invention, which is obtained by Raman spectroscopy. The solid line indicates a measured spectrum, and the dotted-lines indicate spectrums obtained by resolving the measured spectrum. In FIG. 4, a Raman shift appearing at 520 cm⁻¹ represents a crystalline phase of silicon, a Raman shift appearing at 500 cm⁻¹ represents an intermediate phase thereof, and a Raman shift appearing at 480 cm⁻¹ represents an amorphous phase thereof. The volume fraction may be calculated using peak intensity I of the Raman shift of each phase by the following expression: Volume fraction=(I crystalline phase+I intermediate phase)/(I crystalline phase+I intermediate phase+I amorphous phase).

In the present invention, the crystalline silicon layer 105 is preferred to have a high volume fraction, that is, a high ratio of crystal in the film. According to results obtained by evaluating thin-film semiconductors by Raman spectroscopy, among films having a volume fraction of crystal which is equal to or larger than 20%, films having a volume fraction of crystal which is equal to or larger than 40% are particularly preferred. As for a method of forming the crystalline silicon layer, it is preferred to employ a method of depositing the silicon layer by alternately repeating a step of depositing the silicon layer and a step of applying hydrogen plasma. The same may be said with respect to other semiconductor devices according to embodiments described below.

In this embodiment, the crystalline silicon layer 105 serving as an active layer is formed on the titanium oxide layer 104 by, mainly, a CVD method. Here, it was found that the silicon layer formed on the titanium oxide layer 104 had excellent crystallinity compared to a silicon layer formed on a glass substrate (SiO₂) or on other metal oxide, even if the silicon layers were formed in the same condition.

Further, the titanium oxide layer 104 improves crystallinity of, not only the crystalline silicon layer 105 on a rear surface side of a channel, but the crystalline silicon layer 105 stacked on the impurity-containing semiconductor layers 103, and hence a configuration illustrated in FIG. 1B may also be preferred.

In FIG. 1B, the top-gate staggered TFT includes the glass substrate 101, the source and drain electrode layers 102 which are made of a metal, and the impurity-containing semiconductor layers 103. The source and drain electrode layers 102 and the impurity-containing semiconductor layers 103 are formed in an island shape by lamination and patterning similarly to FIG. 1A. Further, the top-gate staggered TFT includes the titanium oxide layer 104. The titanium oxide layer 104 is formed on the glass substrate 101, and on the island-shaped impurity-containing semiconductor layers 103 obtained by patterning. Here, the impurity-containing semiconductor layers 103 are required to have electrical contact to the crystalline silicon layer 105. Therefore, there is employed a method involving forming the titanium oxide layer 104 into a thin film, or by partially exposing the impurity-containing semiconductor layers 103, to thereby form the impurity-containing semiconductor layers 103 and the crystalline silicon layer 105 in direct contact with each other.

In FIGS. 1A and 1B, the top-gate staggered TFT further includes a gate insulating layer 106. The gate insulating layer 106 is preferred to be made of silicon nitride (SiNₓ) or the like, and provides electrical insulation between a gate electrode layer 107 formed by lamination and the crystalline silicon layer 105. In order to insulate side surfaces of the crystalline silicon layer 105, the gate insulating layer 106 may be formed in a two-layer configuration. The gate electrode layer 107 having a desired shape is formed on the gate insulating layer 106 by patterning.

[Bottom-Gate Inverted Staggered TFT]

FIG. 1C illustrates a schematic cross-sectional view of a bottom-gate inverted staggered TFT as another example of the semiconductor device.

In FIG. 1C, the bottom-gate inverted staggered TFT includes, in order from a lower side of FIG. 1C, the glass substrate 101, the gate electrode layer 107, and the gate insulating layer 106. The gate electrode layer 107 is formed in a desired shape by patterning, and then the gate insulating layer 106 is stacked thereon. Further, the bottom-gate inverted staggered TFT includes the source electrode layer 102 and the drain electrode layer 102, which are made of a metal, and the ohmic contact layers serving as the impurity-containing semiconductor layers 103. The source and drain electrode layers 102 and the impurity-containing semiconductor layers 103 are formed in an island shape by lamination and patterning, the lamination being performed on the crystalline silicon layer 105. The titanium oxide layer 104 is formed to have a thickness necessary to for improving the crystallinity of the crystalline silicon layer 105. Further, the titanium oxide layer 104 serves as a gate insulating layer together with the gate insulating layer 106. Therefore, an electrical capacitance is considered so as to determine the film thickness. The titanium oxide layer and the gate insulating layer may not be individually formed of two layers, and may be formed as a single layer. That is, the titanium oxide layer 104 may be used as the gate insulating layer 106. The crystalline silicon layer 105 is formed in contact with the titanium oxide layer 104 on the glass substrate side, and is formed in ohmic contact with the source and drain electrode layers 102 on a side opposite to the glass substrate.

In the bottom-gate inverted staggered TFT, there is a case where a layer such as an oxide film or a nitride film is formed on the crystalline silicon layer 105 on the rear surface side of the channel as a passivation layer.

[Photovoltaic Device]

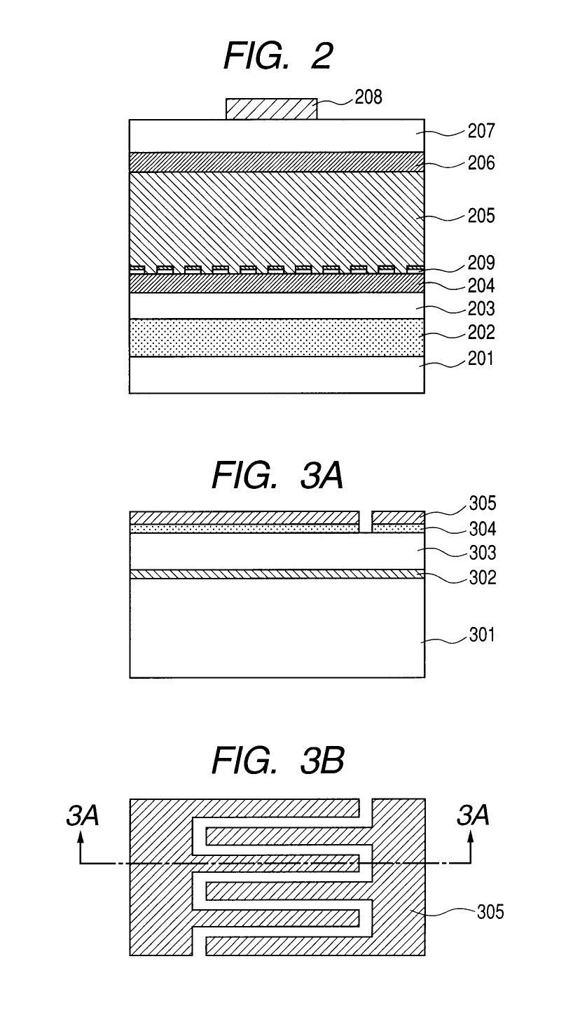

FIG. 2 illustrates a schematic cross-sectional view of a photovoltaic device as still another example of the semiconductor device.

In FIG. 2, the photovoltaic device includes, in order from a lower side of FIG. 2, a conductive substrate 201, a light reflection layer 202, a conductive reflection increasing layer 203, a first conductive layer 204, a titanium oxide layer 209, an i-type layer 205, a second conductive layer 206, a transparent electrode layer 207, and a collector electrode 208. Irradiation light is applied to the photovoltaic device from the transparent electrode layer 207 side.

Further, although not illustrated, a photovoltaic device formed by laminating two or three pin units is also adaptable to the present invention.

In FIG. 2, the titanium oxide layer 209 is formed on the first conductive layer 204. Crystalline silicon is preferred to be used for the first conductive layer 204, the i-type layer 205, and the second conductive layer 206, and as the crystallinity of the crystalline silicon becomes higher, a photoelectric conversion efficiency of the photovoltaic device increases. The i-type layer 205 is the layer which is required to have a particularly high crystallinity. By forming the titanium oxide layer 209 on the first conductive layer 204, the crystallinity of the first conductive layer 204 may be improved. The i-type layer 205 formed thereon grows while taking over crystallinity of the first conductive layer 204, and hence the crystallinity may be further improved. With this, the photoelectric conversion efficiency may be improved.

Here, the first conductive layer 204 is required to have electrical contact to the reflection increasing layer 203 formed under the first conductive layer 204. Therefore, there is employed a method involving forming the titanium oxide layer 209 into a thin film, or by partially exposing the reflection increasing layer 203, to thereby form the first conductive layer 204 and the reflection increasing layer 203 in direct contact with each other.

Note that, in FIG. 2, a device having a PIN junction is exemplified as the photovoltaic device. However, a device having a PN junction, a heterojunction, or a Schottky contact may also be used.

[Photo Sensor]

FIGS. 3A and 3B are a schematic cross-sectional view and a schematic plan view, respectively, of a photo sensor as still another example of the semiconductor device. FIG. 3A is a cross-sectional view taken along the line 3A-3A of FIG. 3B. In FIG. 3A, the photo sensor includes a substrate 301, a titanium oxide layer 302, a photoconductive layer 303 containing crystalline silicon, an ohmic contact layer 304, and an extraction electrode 305. Photo-carriers generated due to incident light are extracted from the extraction electrode 305 through the ohmic contact layer 304 from the photoconductive layer 303. As illustrated in FIG. 3B, the extraction electrode 305 may be formed in a comb shape.

[Production Method of TFT]

Next, a production method of a TFT having the above-mentioned configuration is described with reference to the bottom-gate inverted staggered TFT of FIG. 1C.

First, as illustrated in FIG. 1C, on the substrate 101 made of high-melting-point glass, quartz, ceramic, or the like, the gate electrode layer 107, which is made of Mo, Ti, W, Ni, Ta, Cu, Al, or an alloy thereof, or a laminate thereof, is deposited about 10 to 300 nm thick by sputtering or vacuum evaporation. The gate electrode layer 107 is formed in a desired electrode pattern by etching by photolithography or the like. Further, the gate insulating layer 106 is formed on the gate electrode layer 107 by plasma CVD or the like. Note that, a thickness of the gate insulating layer 106 is preferred to be 50 to 300 nm. SiO₂, SiNₓ, or the like is used to form the gate insulating layer 106. Here, the SiO₂ film or the SiNₓ film is stacked by plasma CVD or the like using a mixed gas of TEOS and O or a mixed gas of SiH₄, NH₃, and N₂.

Next, on the gate insulating layer 106, the titanium oxide layer 104 is formed by sputtering or vacuum evaporation. As for a sputtering method suitable for forming the titanium oxide layer used in the semiconductor device according to the present invention, titanium oxide or titanium metal is used as a target, and an oxygen gas and an argon gas are introduced to allow discharge.

On the titanium oxide layer 104, the crystalline silicon layer 105 is formed by the vapor-phase growth method such as the plasma CVD method. A thickness of the crystalline silicon layer 105 is generally 20 to 200 nm, and is desired to be 40 to 100 nm.

Here, with respect to film formation conditions of the crystalline silicon layer 105, formation under relatively high-pressure and high hydrogen dilution is preferred. RF power density is generally 0.01 to 1 W/cm², and is desired to be 0.1 to 1.0 W/cm². Reaction pressure is generally 133.322 to 1333.22 Pa (1.0 to 10 Torr), and is desired to be 133.322 to 1066.576 Pa (1.0 to 8.0 Torr). Further, a source gas may be SiH₄, Si₂H₆, SiH₂Cl₂, SiF₄, or SiH₂F₂, and a diluent gas may be H₂ or an inert gas. Note that, a flow ratio (H₂/SiH₄) of the silicon source gas with respect to an H₂ gas is generally 100 to 1,000 times diluted. Note that, a preferred value of a dilution ratio is different depending on whether or not the silicon source gas contains a halogen element.

Further, in order to further improve the crystallinity of the crystalline silicon layer 105, it is preferred to employ a method of depositing the crystalline silicon layer while alternately repeating a step of depositing the silicon layer and a step of applying hydrogen plasma. This is possible by arbitrarily adjusting a mass flow controller of the film forming gas. Allocation of time of the steps of deposition and hydrogen plasma irradiation is appropriately adjusted, with consideration of a deposition rate and a ratio of crystallization.

A different layer may be formed on the crystalline silicon layer 105 as an etching stop layer in some cases. The etching stop layer is made of a material which is appropriately selected, such as SiOₓ, SiNₓ, and SiON. The etching stop layer is provided for preventing an etchant from affecting the active layer when the source and drain electrode layers to be stacked thereon are formed in a desired pattern by etching in a following step.

FIG. 1D illustrates an example of a device using the etching stop layer. An etching stop layer 108 is removed in regions where the impurity-containing semiconductor layers 103 and the crystalline silicon layer 105 are caused to be in electrical contact to each other.

Further, after a pattern is formed on a layer which becomes the crystalline silicon layer 105 by a resist, a combination of dry etching and wet etching, or one of dry etching and wet etching is performed. In this manner, the crystalline silicon layer 105 is obtained by pattering.

Next, on the crystalline silicon layer 105, an n-type amorphous silicon layer (n-type semiconductor layer) which becomes the impurity-containing semiconductor layers 103 is formed. A thickness of the n-type amorphous silicon layer is generally 10 to 300 nm, and is desired to be 20 to 100 nm. Further, on the impurity-containing semiconductor layers 103, the source and drain electrode layers 102, which are made of Mo, Ti, W, Ni, Ta, Cu, Al, or an alloy thereof, or a laminate thereof, are formed.

The impurity-containing semiconductor layers 103 and the source and drain electrode layers 102 are formed by, after forming an etching pattern by photolithography based on a design, removing unnecessary portions by dry etching or wet etching with a halogen element.

### EXAMPLES

Next, examples of the embodiments are described.

### Example 1

As illustrated in FIG. 1A, the titanium oxide layer 104 was deposited 10 nm thick on the glass substrate 101 by RF sputtering, under a treatment condition of Film Formation Condition 1. Next, an Mo layer 102 was deposited 50 nm thick by DC sputtering. Further, an n⁺ type Si layer 103 was deposited 30 nm thick by plasma CVD. After that, an etching pattern was formed by photolithography. The Mo layer 102 was patterned by dry etching, to thereby form the source and drain electrode layers 102. At this time, the titanium oxide layer 104 was left unremoved. The crystalline silicon layer 105 was deposited 50 nm thick thereon by plasma CVD, under a treatment condition of Film Formation Condition 2. Then, an etching pattern was again formed by photolithography, and patterning was performed by dry etching.

(Film Formation Condition 1)

| Target | titanium oxide | |
|---|---|---|
| Pressure | 5 | Pa |
| RF Power | 200 | W |
| Ar/O₂ | 50/50 | sccm |

(Film Formation Condition 2)

| Substrate Temperature | 250° | C. |
|---|---|---|
| RF Power | 0.20 | W/cm² |
| Pressure | 666.61 Pa (5.0 Torr) | |
| Film Thickness | 50 | nm |

| | |
|---|---|
| H₂/SiH₄ | 300 |

Next, on the crystalline silicon layer 105 obtained by patterning, a SiNₓ film serving as the gate insulating layer 106 was deposited 200 nm thick by plasma CVD. After that, a positive-type photoresist was applied so as to perform exposure from a rear surface side of the substrate (in this case, source and drain electrode side). In this manner, the photoresist was patterned to a shape of the source and drain electrode layers 102.

Next, on the patterned photoresist, a gate metal layer to become the gate electrode layer 107 was deposited with Mo/Al being 50 nm/500 nm. Next, by lift-off of the photoresist, parts of the gate metal layer formed on the source and drain electrode layers 102 were removed. After that, patterning was performed to obtain the gate electrode layer 107, and thus the top-gate staggered device was obtained. The patterning for obtaining the gate electrode layer 107 was performed by wet etching.

Next, parts of the gate insulating layer 106 formed on contact portions of the source electrode and the drain electrode were removed by photolithography and dry etching.

Then, as for the TFT formed as described above, a sample in a state in which the crystalline silicon layer 105 existed on an outermost surface was also formed. Crystallinity was evaluated by Raman spectroscopy, and electrical characteristics of the sample formed as the TFT were measured.

Electrical measurement was carried out using a 4155C semiconductor parameter analyzer manufactured by Agilent, and the manufactured TFT was measured on a stage maintained at 25° C. Measurement conditions were as follows. Under a state in which voltages of 0 V and 20 V were applied to the source electrode and the drain electrode, respectively, the gate voltage was swept from −20 V to +20 V. A drain current when the gate voltage of 10 V was applied in this condition was defined as an ON current.

Further, a carrier mobility may be obtained by a slope of the drain current (Id) when the gate voltage (VG) was swept, and may be obtained by the following expression “Mobility=A·Δ√(Id)/ΔVG”, where A denotes a constant resulting from shapes of the source and drain electrode layers and a capacitance of the gate insulating layer. From this expression, the carrier mobility was obtained.

### Comparative Example 1

In this comparative example, a top-gate staggered device and a sample in a state in which the crystalline silicon layer 105 existed on an outermost surface were formed similarly to Example 1, except for not forming the titanium oxide layer 104. Similarly to Example 1, the electrical measurement was performed, and the carrier mobility and the crystallinity were evaluated.

As a result, the device according to Example 1 exhibited excellent electrical characteristics in comparison with those of Comparative Example 1, that is, a 5 times larger ON current and a 2 times larger carrier mobility. Further, according to evaluation of crystallinity obtained by Raman spectroscopy, as for the volume fraction of crystal, which was obtained by a peak intensity ratio between 520 cm⁻¹, 500 cm⁻¹, and 480 cm⁻¹, Example 1 was 40% and Comparative Example 1 was 30%. Although both Example 1 and Comparative Example 1 obtained crystalline silicon, the crystallinity of Example 1 was 1.3 times higher than that of Comparative Example 1.

As described above, in Example 1, by forming the crystalline silicon layer in contact with the titanium oxide layer, the crystallinity of the crystalline silicon layer may be improved.

### Example 2

As illustrated in FIG. 1C, the bottom-gate inverted staggered TFT device was formed on the glass substrate 101. The gate electrode layer 107, the gate insulating layer 106, the impurity-containing semiconductor layers 103, and the source and drain electrode layers 102 were formed as in [Production Method of TFT] described above.

Similarly to Example 1, the titanium oxide layer 104 was deposited 30 nm thick by RF sputtering, under a treatment condition of Film Formation Condition 3. Further, the crystalline silicon layer 105 was formed 80 nm thick under a treatment condition of Film Formation Condition 4.

(Film Formation Condition 3)

| Target | titanium oxide | |
|---|---|---|
| Pressure | 1 | Pa |
| RF Power | 150 | W |
| Ar/O₂ | 30/30 | sccm |

(Film Formation Condition 4)

| Substrate Temperature | 300° | C. |
|---|---|---|
| RF Power | 0.20 | W/cm² |
| Pressure | 1333.22 Pa (10 Torr) | |
| Film Thickness | 80 | nm |

| | |
|---|---|
| H₂/SiH₄ | 600 |

Then, similarly to the TFT formed as described above, a sample in a state in which the crystalline silicon layer 105 existed on an outermost surface was also formed, and crystallinity was evaluated similarly to Example 1, electrical characteristics and a carrier mobility of the sample formed as the TFT were measured.

### Comparative Example 2

In this comparative example, a bottom-gate inverted staggered device and a sample in a state in which the crystalline silicon layer 105 existed on an outermost surface were formed similarly to Example 2, except for not forming the titanium oxide layer 104. Similarly to Example 2, evaluation was performed.

As a result, the device according to Example 2 exhibited excellent electrical characteristics in comparison with those of Comparative Example 2, that is, a 10 times larger ON current and a 2 times larger carrier mobility. Further, according to evaluation of crystallinity obtained by Raman spectroscopy, as for the volume fraction of crystal, which was obtained by a peak intensity ratio between 520 cm⁻¹, 500 cm⁻¹, and 480 cm⁻¹, Example 2 was 36% and Comparative Example 2 was 30%. Although both Example 2 and Comparative Example 2 obtained crystalline silicon, the crystallinity of Example 2 was 1.2 times higher than that of Comparative Example 2.

As described above, in Example 2, similarly to Example 1, by forming the crystalline silicon layer in contact with the titanium oxide layer, the crystallinity of the crystalline silicon layer may be improved.

### Example 3

The photovoltaic device illustrated in FIG. 2 was formed. First, on the SUS304 substrate 201, by using a DC magnetron sputtering apparatus, an AlSi layer serving as the light reflection layer 202 was formed at a thickness of 500 nm, and then, a zinc oxide layer serving as the reflection increasing layer 203 was formed at a thickness of 2,000 nm by reactive sputtering. Next, the substrate, which had been treated up to the formation of the zinc oxide layer, was placed on a plasma CVD apparatus, and the first conductive layer 204 was formed. Here, a PH₃/H₂ gas was introduced to form an n⁺ type silicon layer having a thickness of 10 nm.

Next, the substrate was placed on an RF magnetron sputtering apparatus, and the titanium oxide layer 209 having a thickness of 30 nm was formed under a treatment condition of Film Formation Condition 5. After the titanium oxide layer 209 had been formed, dot-shaped contact holes were formed in the titanium oxide layer 209 by photolithography. Next, on the titanium oxide layer 209, the i-type crystalline silicon layer 205 having a thickness of 1,000 nm was formed by plasma CVD, under a treatment condition of Film Formation Condition 6. The second conductive layer 206 was formed on the crystalline silicon layer 205. Here, a BF₃/H₂ gas was introduced to form a p⁺ type silicon layer having a thickness of 10 nm.

Next, the transparent electrode layer 207 made of indium tin oxide (ITO) having a thickness of 80 nm was formed by using a deposition apparatus. Finally, an Al electrode film to become the collector electrode 208 was formed at a thickness of 500 nm by using the DC magnetron sputtering apparatus, and patterning was performed.

(Film Formation Condition 5)

| Target | titanium oxide | |
|---|---|---|
| Pressure | 10 | Pa |
| RF Power | 150 | W |
| Ar/O₂ | 100/100 | sccm |

(Film Formation Condition 6)

| Substrate Temperature | 200° | C. |
|---|---|---|
| RF Power | 0.30 | W/cm² |
| Pressure | 666.61 Pa (5.0 Torr) | |
| Film Thickness | 1,000 | nm |

| | |
|---|---|
| H₂/SiH₄ | 200 |

Then, as for the photovoltaic device formed as described above, a sample in a state in which the crystalline silicon layer 205 existed on an outermost surface was also formed, and crystallinity was evaluated. Photoelectric conversion efficiency of the sample formed as the photovoltaic device was measured using an AM 1.5 solar simulator.

### Comparative Example 3

In this comparative example, a photovoltaic device was formed similarly to Example 3, except for not forming the titanium oxide layer 209. Similarly to Example 3, evaluation was performed.

As a result, compared with the photovoltaic device according to Comparative Example 3, the photovoltaic device according to Example 3 was higher in photoelectric conversion efficiency. Further, according to evaluation of crystallinity obtained by Raman spectroscopy, in Example 3, the volume fraction of crystal, which was obtained by a peak intensity ratio between 520 cm⁻¹ and 480 cm⁻¹, was 1.2 times higher than that of Comparative Example 3.

As described above, in Example 3, similarly to Examples 1 and 2, by forming the crystalline silicon layer in contact with the titanium oxide layer, the crystallinity of the crystalline silicon layer may be improved.

This application claims the benefit of Japanese Patent Application No. 2009-274620, filed Dec. 2, 2009, which is hereby incorporated by reference herein in its entirety.

1. A semiconductor device, comprising:
a substrate;
a crystalline silicon layer;
a titanium oxide layer containing titanium oxide as a main component; and
a pair of electrodes electrically connected to the crystalline silicon layer; wherein:
the titanium oxide layer and the crystalline silicon layer are formed on the substrate in the mentioned order from the substrate side; and
the titanium oxide layer and the crystalline silicon layer are in contact with each other.

2. The semiconductor device according to claim 1, further comprising a gate insulating layer and a gate electrode layer which are formed on the substrate, wherein:
the pair of electrodes comprise a source electrode layer and a drain electrode layer;
the gate electrode layer, the gate insulating layer, and the titanium oxide layer are stacked in the mentioned order; and
the crystalline silicon layer is in ohmic contact with the source electrode layer and the drain electrode layer on a side opposite to the substrate.

3. The semiconductor device according to claim 1, further comprising a gate electrode layer which is formed on the substrate, wherein:
the pair of electrodes comprise a source electrode layer and a drain electrode layer;
the gate electrode layer and the titanium oxide layer are stacked in the mentioned order;
the titanium oxide layer also serves as a gate insulating layer; and
the crystalline silicon layer is in ohmic contact with the source electrode layer and the drain electrode layer on a side opposite to the substrate.

4. The semiconductor device according to claim 1, further comprising a gate insulating layer and a gate electrode layer which are formed on the substrate, wherein:
the pair of electrodes comprise a source electrode layer and a drain electrode layer;
the crystalline silicon layer, the gate insulating layer, and the gate electrode layer are stacked in the mentioned order; and
the crystalline silicon layer is in ohmic contact with the source electrode layer and the drain electrode layer on the substrate side.

5. The semiconductor device according to claim 1, wherein:
the crystalline silicon layer has one of a PN junction, a PIN junction, a heterojunction, and a Schottky contact; and
among the pair of electrodes, one electrode is electrically connected to the crystalline silicon layer on the substrate side, and another electrode is electrically connected to the crystalline silicon layer on a side opposite to the substrate.

6. A production method of a semiconductor device, comprising:
forming a titanium oxide layer containing titanium oxide as a main component; and
forming a crystalline silicon layer by a vapor-phase growth method, the crystalline silicon layer being formed in contact with the titanium oxide layer.

7. The production method of a semiconductor device according to claim 6, wherein the forming a crystalline silicon layer by a vapor-phase growth method comprises forming a silicon layer by a CVD method and applying hydrogen plasma, the forming a silicon layer and the applying hydrogen plasma being alternately repeated.
